(19) United States
(12) Patent Application Publication
(10) Pub. No.: US 2026/0372174 A1
(43) Pub. Date: Nov. 19, 2026

(54) STRUCTURE AND FORMATION METHOD OF PACKAGE WITH MOLDING STRUCTURES

(71) Applicant: Taiwan Semiconductor Manufacturing Company, Ltd., Hsinchu (TW)

(72) Inventors: Po-Chen LAI, Hsinchu county (TW); Ming-Chih YEW, Hsinchu City (TW); Kuo-Chin CHANG, Chiayi City (TW); Kathy Wei YAN, Hsinchu (TW); Chen-Shien CHEN, Zhubei City (TW)

(73) Assignee: Taiwan Semiconductor Manufacturing Company, Ltd., Hsinchu (TW)

(21) Appl. No.: 19/211,937

(22) Filed: May 19, 2025

(51) Int. Cl. H10W 74/10; H10W 90/00

(52) U.S. Cl. CPC H10W 74/121; H10W 90/00; H10W 90/792

(57) ABSTRACT

A package structure and a method for forming a package structure are provided. The package structure includes a first upper chip-containing structure and a second upper-chip-containing structure over a lower chip-containing structure. The package structure also includes a first molding structure laterally surrounding the first upper chip-containing structure and the second upper chip-containing structure. The package structure further includes a second molding structure laterally surrounded by the first molding structure. Some or all of the second molding structure is between the first upper chip-containing structure and the second upper chip-containing structure.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A chip package not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1L are cross-sectional views of various stages of a process for forming portion of a package structure, in accordance with some embodiments.

FIG. 2 is a top view of a portion of a package structure, in accordance with some embodiments.

FIG. 3 is a cross-sectional view of a portion of a package structure, in accordance with some embodiments.

FIG. 4 is a cross-sectional view of a portion of a package structure, in accordance with some embodiments.

FIG. 5 is a cross-sectional view of a portion of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure and/or the package structure. Some of the features described below can be replaced or eliminated for different embodiments. Although some embodiments are discussed with operations performed in a particular order, these operations may be performed in another logical order.

Embodiments of the disclosure may relate to three-dimensional (3D) packaging or 3D-IC devices. Other features and processes may also be included. For example, testing structures may be included to aid in the verification testing of the 3D packaging or 3D-IC devices. The testing structures may include, for example, test pads formed in a redistribution layer or on a substrate that allows the testing of the 3D packaging or 3D-IC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

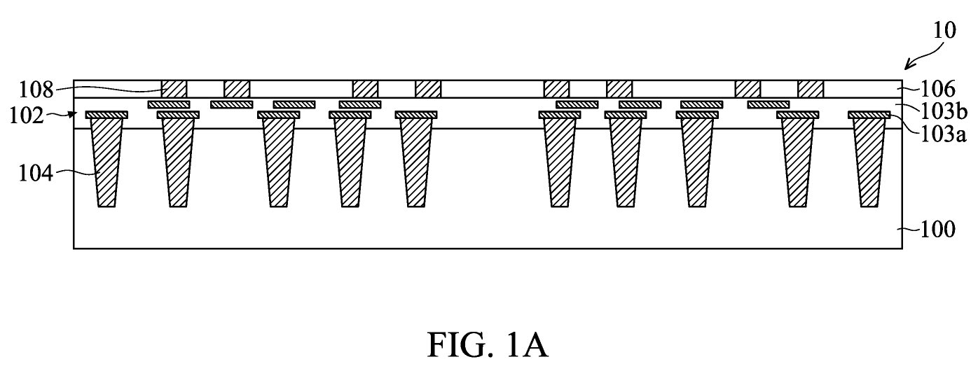

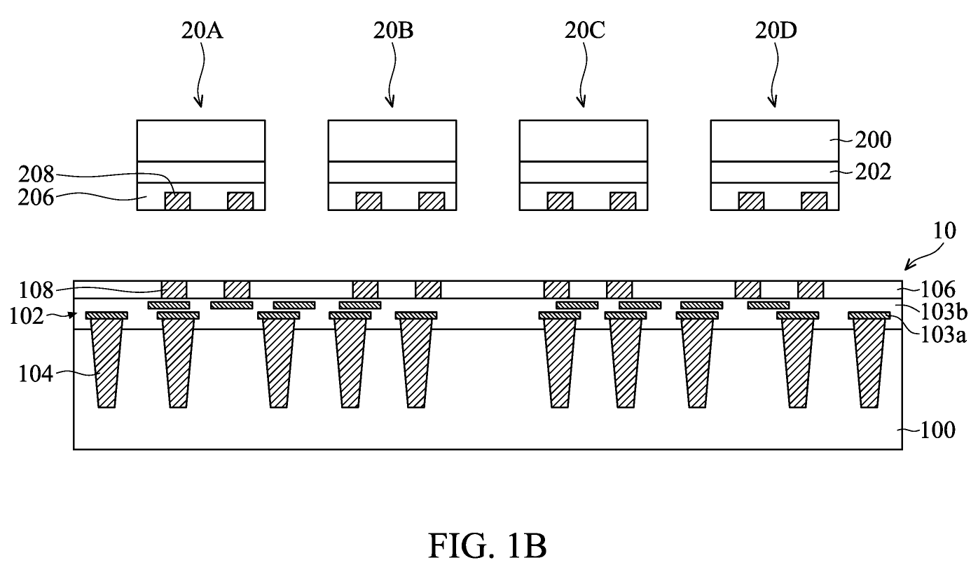

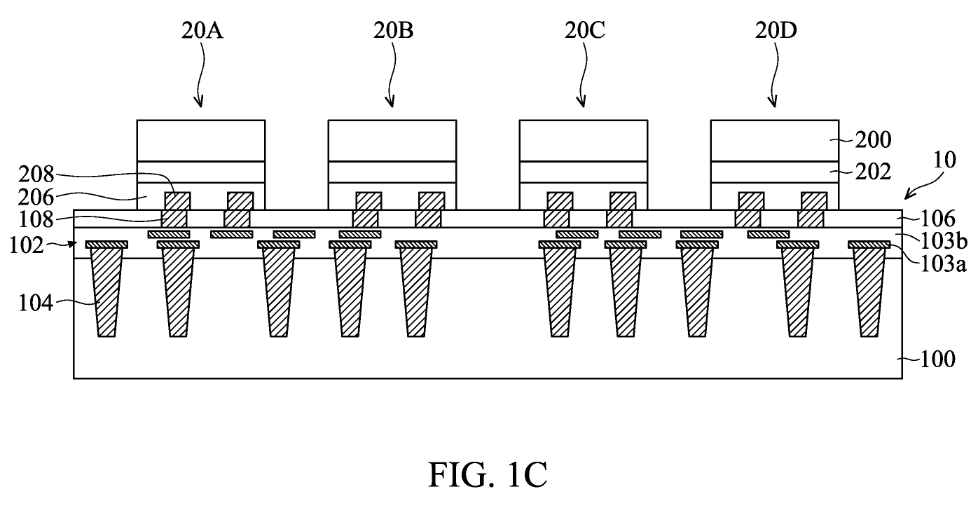

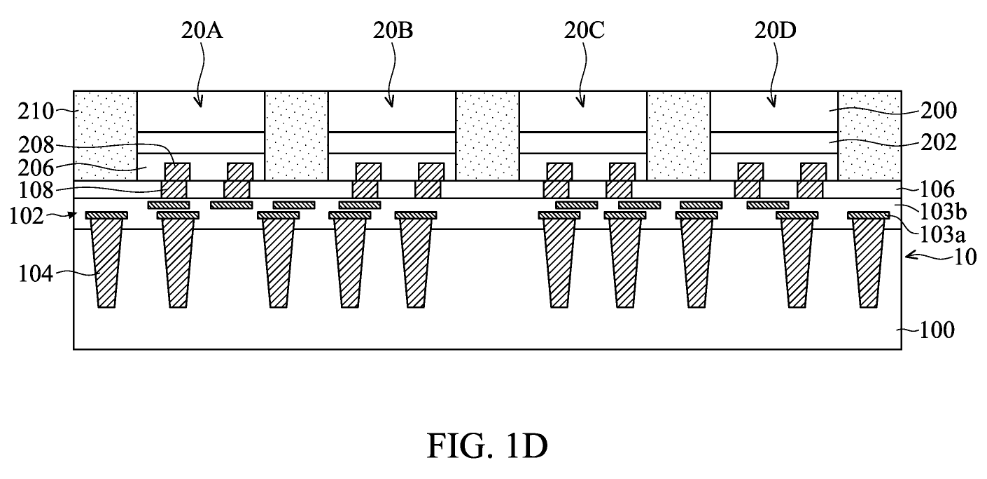

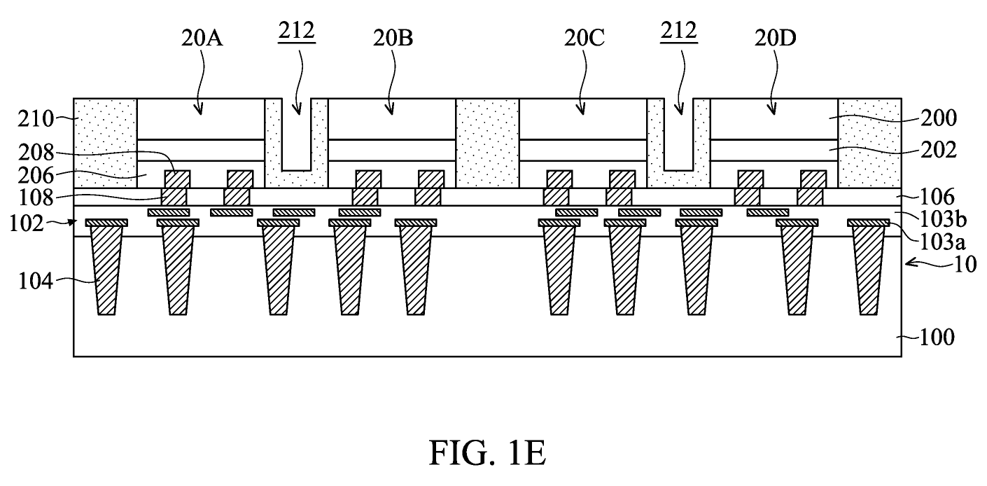

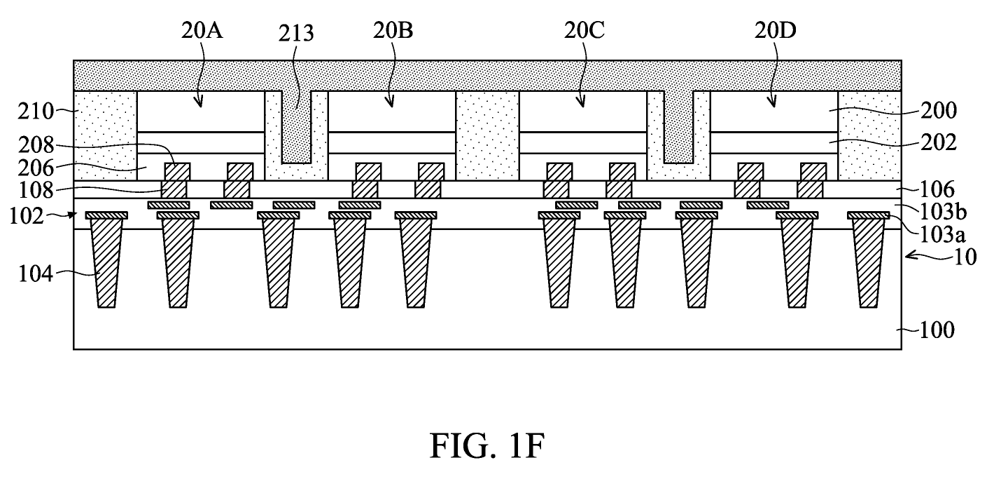

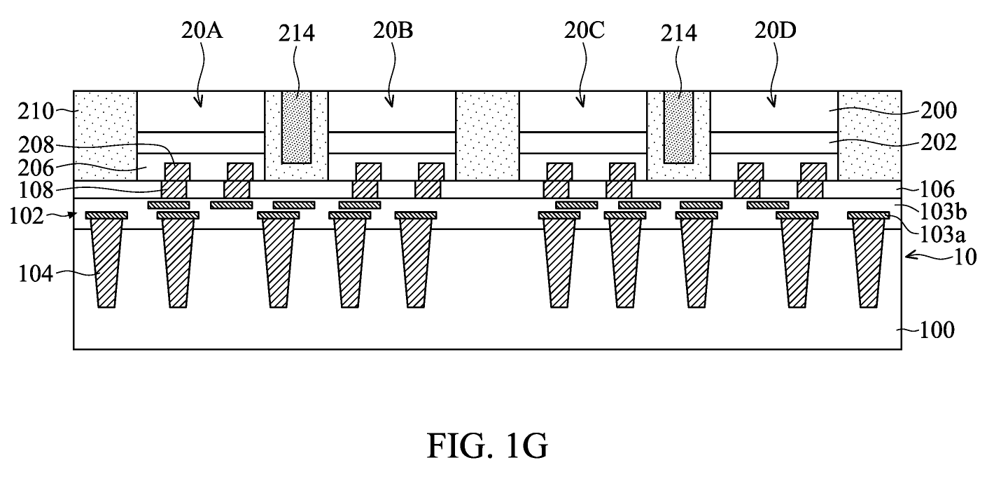

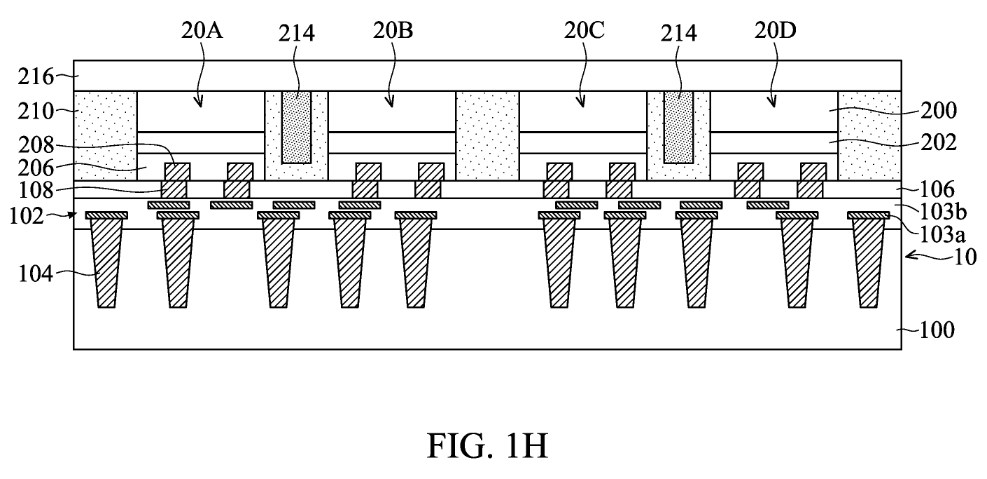

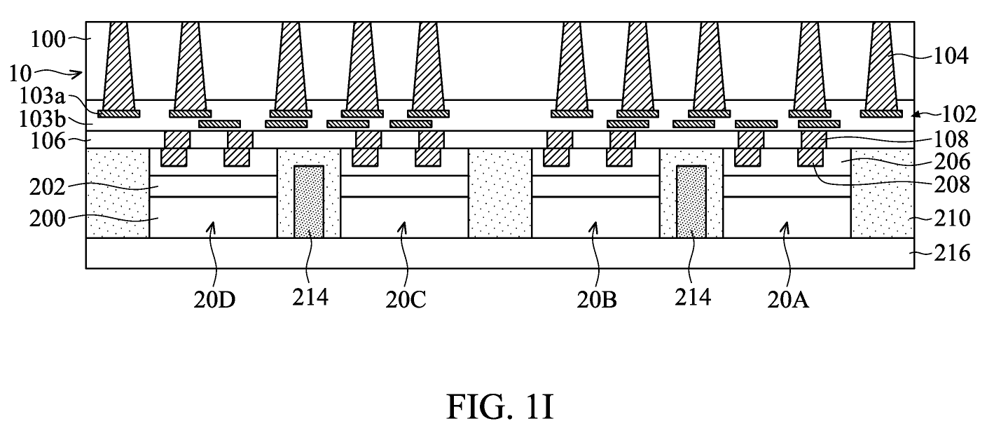

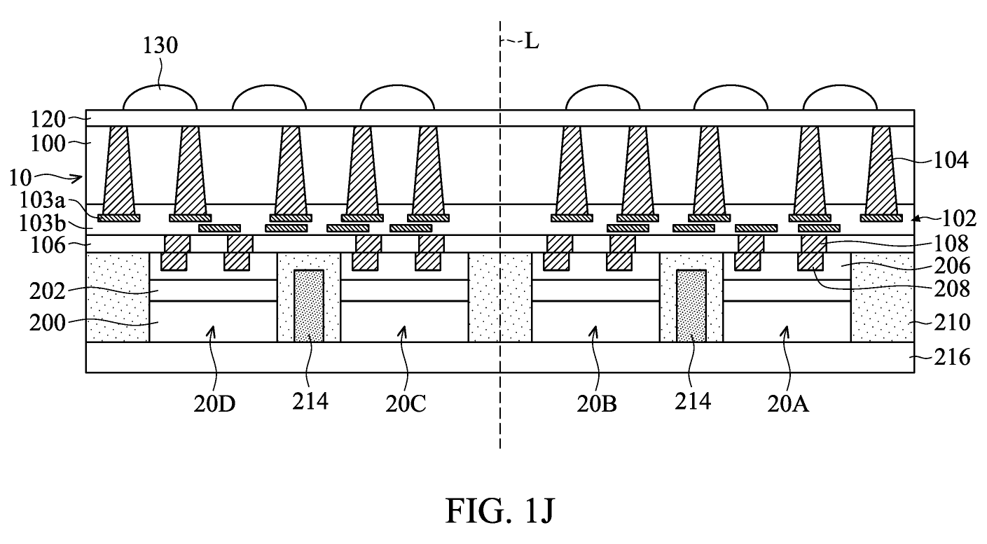

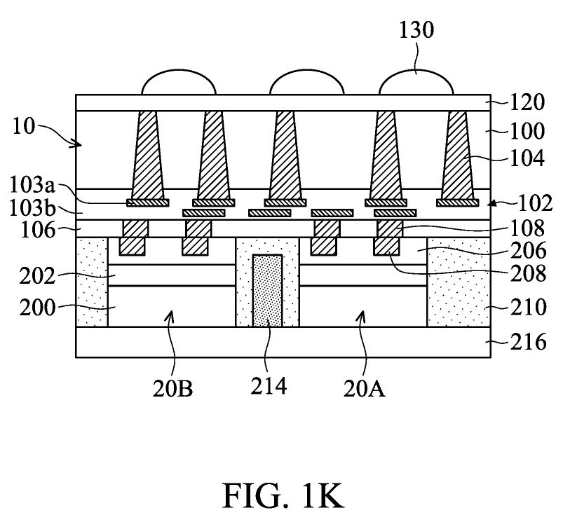

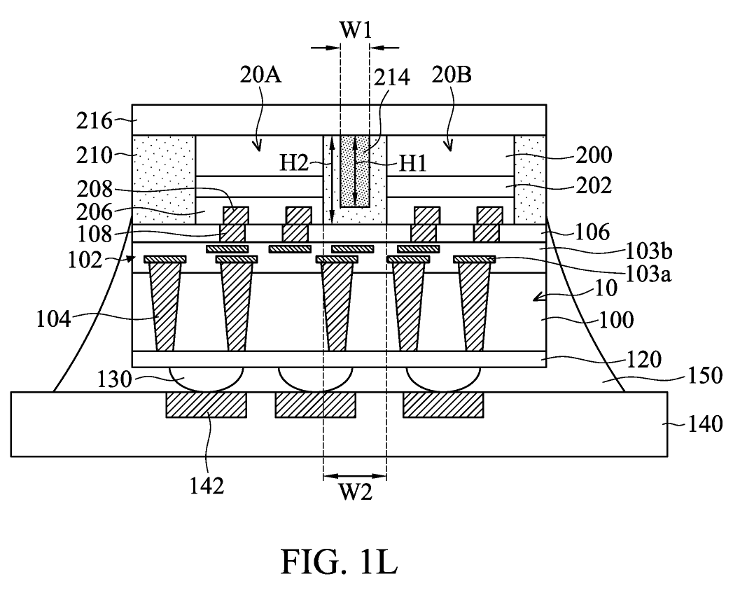

FIGS. 1A-1L are cross-sectional views of various stages of a process for forming a portion of a package structure, in accordance with some embodiments. As shown in FIG. 1A, a chip-containing structure 10 is received, in accordance with some embodiments. In some embodiments, the chip-containing structure 10 is a semiconductor wafer that includes multiple chip regions that are surrounded by the scribe line region. After a subsequent sawing process, multiple semiconductor chips that are separated from each other may be obtained.

In some embodiments, the chip-containing structure 10 includes a semiconductor substrate 100. The semiconductor substrate 100 may include silicon or another elementary semiconductor material such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate includes a silicon-germanium layer formed on a bulk silicon layer.

Various device elements are formed in or over the semiconductor substrate in the device regions of the semiconductor substrate 100. The device regions may be located near the top surface of the semiconductor substrate 100. Examples of the various device elements include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or another suitable element. Various processes may be used to form the various device elements, including deposition, etching, implantation, photolithography, annealing, and other suitable processes.

The chip-containing structure 10 may include an interconnection structure 102 such as a front-side interconnection structure. The interconnection structure 102 includes multiple conductive features 103a and a dielectric structure 103b that contains multiple dielectric layers. The interconnection structure 102 also includes multiple metal bonding structures 108 that are surrounded by a dielectric bonding structure 106. The dielectric bonding structure 106 may include one or multiple dielectric layers. The conductive features 103a in the interconnection structure 102 may include conductive lines, conductive pads, conductive contacts, and conductive vias.

The dielectric layers of the dielectric bonding structure 106 and the dielectric structure 103b may be made of or include silicon oxide, silicon oxynitride, silicon nitride, carbon-containing silicon oxide, carbon-containing silicon nitride, carbon-containing silicon oxynitride, another suitable material, or a combination thereof. The conductive features 103a may be made of or include copper, tungsten, cobalt, aluminum, tantalum, gold, another suitable material, or a combination thereof. The formation of the interconnection structure 102 may involve multiple deposition processes, patterning processes, planarization processes, another applicable process, or a combination thereof. In some embodiments, a chemical mechanical polishing (CMP) process is performed to ensure that the surface of the chip-containing structure 10 is highly planarized. The top surfaces of the metal bonding structures 108 and the dielectric bonding structure 106 are level.

The device elements of the chip-containing structure 10 are interconnected by the interconnection structure 102 to form integrated circuit devices, such as logic devices, memory devices (e.g., static random access memory, SRAM), radio frequency (RF) devices, input/output (I/O) devices, one or more other types of devices, or a combination thereof.

In some embodiments, multiple conductive structures 104 are formed in the chip-containing structure 10, as shown in FIG. 1A. The conductive structures 104 are laterally surrounded by the semiconductor substrate 100 and the interconnection structure 102. In some embodiments, a dielectric layer is formed between the semiconductor substrate 100 and the conductive structures 104 to prevent short-circuiting between the semiconductor substrate 100 and the conductive structures 104. In some embodiments, each of the conductive structures 104 is electrically connected to some of the conductive features 103a formed in the interconnection structure 102.

As shown in FIG. 1B, multiple chip-containing structures 20A, 20B, 20C, and 20D are provided and prepared for bonding to the chip-containing structures 10, in accordance with some embodiments. Similar to the chip-containing structure 10, each of the chip-containing structures 20A-20D includes a semiconductor substrate 200, an interconnection structure 202, a dielectric bonding structure 206, and multiple metal bonding structures 208.

The semiconductor substrate 200 may include silicon or another elementary semiconductor material such as germanium. The semiconductor substrate 200 may be un-doped or doped (e.g., p-type, n-type, or a combination thereof). In some embodiments, the semiconductor substrate 200 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 200 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 200 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 200 includes a multi-layered structure. For example, the semiconductor substrate 200 includes a silicon-germanium layer formed on a bulk silicon layer.

Various device elements are formed in or over the semiconductor substrate 200. Examples of the various device elements include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or another suitable element. Various processes may be used to form the various device elements, including deposition, etching, implantation, photolithography, annealing, and other suitable processes.

The interconnection structure 202 includes multiple conductive features and multiple dielectric layers. The interconnection structure 202 also includes multiple metal bonding structures 208 that are surrounded by a dielectric bonding structure 206. The dielectric bonding structure 206 may include one or multiple dielectric layers. The conductive features in the interconnection structure 202 may include conductive lines, conductive pads, conductive contacts, and conductive vias. In FIG. 1B, the conductive features are not shown for the sake of clarity and simplicity.

The dielectric layers of the dielectric bonding structure 206 may be made of or include silicon oxide, silicon oxynitride, silicon nitride, carbon-containing silicon oxide, carbon-containing silicon nitride, carbon-containing silicon oxynitride, another suitable material, or a combination thereof. The conductive features may be made of or include copper, tungsten, cobalt, aluminum, tantalum, gold, another suitable material, or a combination thereof. The formation of the interconnection structure may involve multiple deposition processes, patterning processes, planarization processes, another applicable process, or a combination thereof. In some embodiments, a CMP process is performed to ensure that the surfaces of the chip-containing structures 20A-20D is highly planarized. For each of the chip-containing structures 20A-20D, the surfaces of the metal bonding structures 208 and the dielectric bonding structure 206 are level.

The device elements of each of the chip-containing structures 20A-20B are interconnected by the interconnection structure 202 to form integrated circuit devices, such as logic devices, memory devices (e.g., static random access memory, SRAM), radio frequency (RF) devices, input/output (I/O) devices, one or more other types of devices, or a combination thereof.

Afterwards, as shown in FIG. 1C, the chip-containing structures 20A-20D are bonded to the chip-containing structure 10 through direct bonding, in accordance with some embodiments. The direct bonding may include dielectric-to-dielectric bonding and metal-to-metal bonding. In some embodiments, there is no tin-containing solder elements or solder bump formed between the lower chip-containing structure (i.e., the chip-containing structure 10) and the upper chip-containing structures (i.e., the chip-containing structures 20A-20D). In some embodiments, the bonding therebetween is a bumpless thermo-compression bonding.

In some embodiments, the chip-containing structures 20A-20D are placed directly on the dielectric bonding structure 106 and the metal bonding structures 108 of the chip-containing structure 10. As a result, the dielectric bonding structure 106 of the chip-containing structure 10 is in direct contact with the dielectric bonding structures 206 of the chip-containing structures 20A-20D. The metal bonding structures 108 of the chip-containing structure 10 are in direct contact with the metal bonding structures 208 of the chip-containing structures 20A-20D.

Before the placing of the chip-containing structures 20A-20D, planarization processes are performed, so as to provide highly planarized bonding surfaces. In some embodiments, there is no gap between the dielectric bonding structures 106 and 206. In some embodiments, there is no gap between the metal bonding structures 108 and 208.

In some embodiments, a thermal operation is then used to enhance the bonding between the metal bonding structures 108 and 208. The temperature of the thermal operation may within a range from about 100 degrees C to about 500 degrees C. In some embodiments, a thermo-compression process is used to enhance the bonding between the chip-containing structure 10 and the chip-containing structures 20A-20D.

As shown in FIG. 1D, a molding structure 210 is formed to laterally surround the chip-containing structures 20A-20D, in accordance with some embodiments. In some embodiments, a molding liquid is introduced into the space between the chip-containing structure 10 and a mold placed above the chip-containing structures 10 and 20A-20D. The molding liquid is constrained by the mold, forming a molding material that laterally surrounds the chip-containing structures 20A-20D.

Afterwards, a thermal operation is used to cure the molding material, in accordance with some embodiments. As a result, the molding material is cured to form the molding structure 210. The molding structure 210 may be made of or include a polymer material, such as an epoxy-based resin with fillers dispersed therein. The epoxy-based resin may include multi-aromatic epoxy resin, biphenyl epoxy resin, another suitable material, or a combination thereof. The fillers may include fibers (such as silica fibers and/or carbon-containing fibers), particles (such as silica particles and/or carbon-containing particles), or a combination thereof. In some embodiments, the molding structure 210 provides better thermal dissipation efficiency and is more cost-effective compared to an oxide gap-filling material.

As shown in FIG. 1E, the molding structure 210 is partially removed to form multiple openings 212, in accordance with some embodiments. In some embodiments, one of the openings 212 is located between the chip-containing structures 20A and 20B, and one of the openings 212 is located between the chip-containing structures 20C and 20D. In some embodiments, the openings 212 are trenches. The openings 212 may be formed using one or more laser drilling processes, one or more cutting processes, a patterning process involving a photolithography process and an etching process, another applicable process, or a combination thereof.

The shape of the openings 212 may be adjusted as needed. In some embodiments, the openings 212 have vertical sidewalls. In some embodiments, the openings 212 have slanted sidewalls. In some embodiments, the openings 212 have rounded bottom surfaces. In some embodiments, the openings 212 have slanted sidewalls and rounded bottom surfaces.

As shown in FIG. 1F, a molding layer 213 is formed over the molding structure 210 and the chip-containing structures 20A-20D, in accordance with some embodiments. The material of the molding layer 213 may be similar to but distinct from that of the molding structure 210. The formation method of the molding layer 213 may be the same as or similar to that of the molding structure 210. In some embodiments, the fillers in the molding layer 213 and the molding structure 210 have different materials, different distribution densities, different sizes, and/or different profiles.

The molding layer 213 may be made of or include a polymer material, such as an epoxy-based resin with fillers dispersed therein. The epoxy-based resin may include multi-aromatic epoxy resin, biphenyl epoxy resin, another suitable material, or a combination thereof. The fillers may include fibers (such as silica fibers and/or carbon-containing fibers), particles (such as silica particles and/or carbon-containing particles), or a combination thereof.

In some embodiments, the Young’s modulus of the molding layer 213 differs from that of the molding structure 210. In some embodiments, the molding layer 213 has a greater Young’s modulus than that of the molding structure 210. The Young’s modulus the molding structure 210 and the molding layer 213 may be measured using a nano-indenter. The ratio of the Young’s modulus of the molding layer 213 to the Young’s modulus of the molding structure 210 may be within a range from about 1.2 to about 3.

As shown in FIG. 1G, the molding layer 213 is partially removed using a planarization process, in accordance with some embodiments. As a result, the remaining portions of the molding layer 213 form multiple molding structures 214. The planarization process may include a CMP process, a grinding process, another applicable process, or a combination thereof. The molding structures 214 extend downwards from the top surface of the molding structure 210 towards the chip-containing structure 10.

As shown in FIG. 1H, a carrier substrate 216 is bonded to the chip-containing structures 20A-20D and the molding structures 210 and 214, in accordance with some embodiments. The carrier substrate 216 may be a semiconductor substrate such as a silicon wafer. Alternatively, the carrier substrate 216 may be a dielectric substrate such as a glass wafer. The carrier substrate 216 may be bonded to the chip-containing structures 20A-20D using an oxide bonding process. In some other embodiments, an adhesive layer is used to attach the carrier substrate 216 is bonded to the chip-containing structures 20A-20D and the molding structures 210 and 214.

As shown in FIG. 1I, the semiconductor substrate 100 of the chip-containing structure 10 is thinned and then turned upside shown, in accordance with some embodiments. After the semiconductor substrate 100 is thinned, the conductive structures 104 are exposed. The semiconductor substrate 100 may be thinned using a planarization process such as a CMP process. The conductive structures 104 may serve as through substrate vias (TSVs) that provide electrical connections between elements formed on opposite surfaces of the semiconductor substrate 100.

As shown in FIG. 1J, a redistribution structure 120 and multiple conductive connectors 130 are sequentially formed over the semiconductor substrate 100 and the conductive structures 104, in accordance with some embodiments. The redistribution structure 120 may include multiple insulating layers and multiple conductive features for routing. Multiple coating processes, multiple plating processes, multiple patterning processes, and multiple planarization processes may be used to form the redistribution structure 120.

The conductive connectors 130 may include solder bumps. The solder bumps may be made of a tin-containing material. The tin-containing material may further include copper, silver, gold, aluminum, lead, one or more other suitable materials, or a combination thereof. In some other embodiments, the solder bumps are lead-free.

Afterwards, in some embodiments, a sawing process is used to separate the structure into multiple package structures. For example, the structure shown in FIG. 1J may be cut along the line L. As a result, multiple packages structure are formed. One of the package structures is shown in FIG. 1K.

In some embodiments, the chip-containing structure 10 is originally a portion of a reconstructed semiconductor wafer. After the sawing process, the chip-containing structure 10 shown in FIG. 1K may be a single semiconductor chip. The package structure shown in FIG. 1K may function as a system on integrated chips that may further be integrated into another package structure.

In some embodiments, the carrier substrate 216 is removed before the sawing process. In some embodiments, a thermal conductive lid is formed over the chip-containing structures 20A-20D after the removal of the carrier substrate 216. In some other embodiments, the carrier substrate 216 is not removed. In some embodiments, a thermal conductive lid is formed over the carrier substrate 216.

As shown in FIG. 1L, the package structure shown in FIG. 1K is further bonded to bonding pads 142 of a substrate 140 through the conductive connectors 130, in accordance with some embodiments. In some embodiments, an underfill element 150 is formed over the substrate 140 to laterally surround and to protect the conductive connectors 130. The substrate 140 may include a circuit board, a semiconductor interposer, or another suitable substrate.

The molding structure 214 may help reinforce the critical chip-to-chip area, providing sufficient mechanical strength and stiffness. This significantly reduces deformations in the chip-to-chip gap area, preventing bonding layer cracking, delamination, and electrical failures. As a result, the performance and reliability of the package structure are greatly enhanced.

As shown in FIG. 1L, the chip-containing structures 20A and 20B are separated from each other by a distance W2 along the lateral direction. The molding structure 214 has a width W1 measured along the lateral direction. In some embodiments, the distance W2 is greater than the width W1. In some embodiments, the ratio (W1/W2) of the width W1 to the distance W2 is within a range from about 0.5 to about 0.9.

In some cases, if the ratio (W1/W2) is less than about 0.5, the molding structure 214 may not be able to provide sufficient mechanical strength and stiffness to effectively reinforce the critical chip-to-chip area. In some other cases, if the ratio (W1/W2) is greater than about 0.9, the molding structure 214 may be too close to the chip-containing structures 20A and 20B, increasing the risk of damage to the chip-containing structures 20A and 20B during the formation of the molding structure 214.

As shown in FIG. 1L, the molding structure 214 has a height H1, and the molding structure 210 has a height H2. In some embodiments, the height H2 is greater than the height H1. In some embodiments, the ratio (H1/H2) of the height H1 to the height H2 is within a range from about 0.5 to about 0.9.

In some cases, if the ratio (H1/H2) is less than about 0.5, the molding structure 214 may not be able to provide sufficient mechanical strength and stiffness to effectively reinforce the critical chip-to-chip area. In some other cases, if the ratio (H1/H2) is greater than about 0.9, the molding structure 214 may be too close to the chip-containing structure 10, increasing the risk of damage to the chip-containing structure 10 during the formation of the molding structure 214.

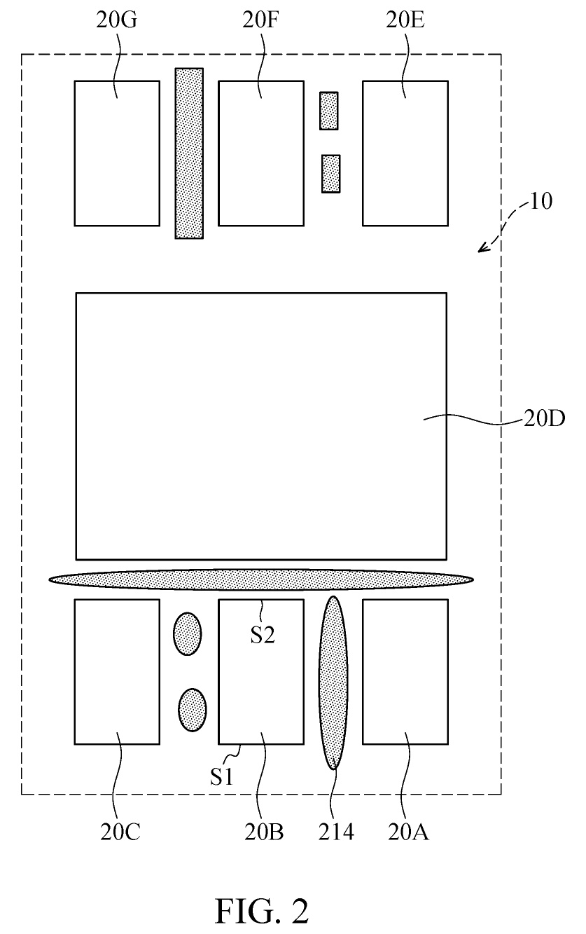

FIG. 2 is a top view of a portion of a package structure, in accordance with some embodiments. The package structure shown in FIG. 2 is similar to the package shown in FIG. 1K. In some embodiments, multiple chip-containing structures 20A-20G are placed over the chip-containing structure 10, as shown in FIG. 2. In some embodiments, multiple molding structures 214 are formed over the chip-containing structure 10. The molding structures 214 are laterally surrounded by the molding structure 210. The molding structures 214 are formed within the gap between the nearby chip-containing structures. In FIG. 2, for the sake of clarity and simplicity, the molding structure 210 and the carrier substrate 216 are not shown.

The molding structures 214 may have various top view shape such as oval, rectangle, square, or another suitable shape. In some embodiments, one of the molding structures 214 extends across opposite side edges S1 and S2 of the chip-containing structure 20B, as shown in FIG. 2. In some embodiments, one of the molding structures 214 extends across opposite side edges of the chip-containing structures 20A-20G.

The molding structures 214 help reinforce the critical chip-to-chip area, providing sufficient mechanical strength and stiffness. This significantly reduces deformations in the chip-to-chip gap area, preventing bonding layer cracking, delamination, and electrical failures. As a result, the performance and reliability of the package structure are greatly enhanced.

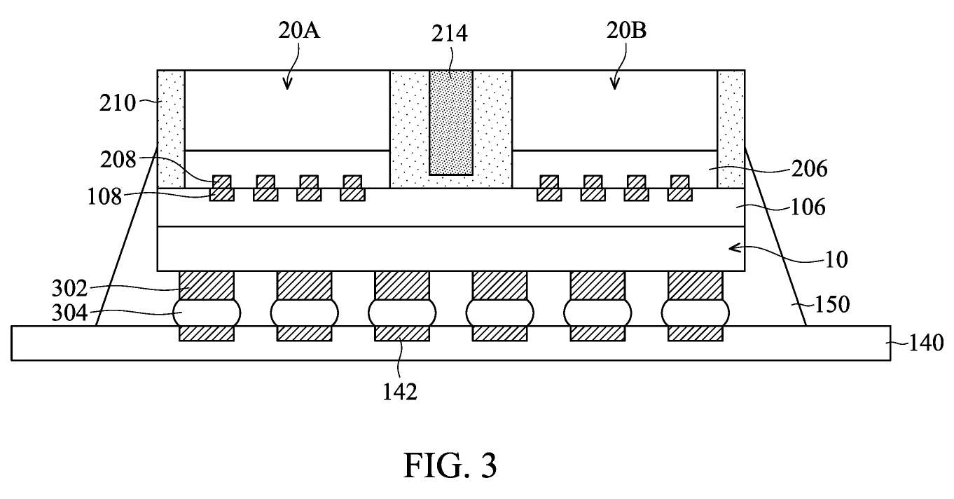

Many variations and/or modifications can be made to embodiments of the disclosure. FIG. 3 is a cross-sectional view of a portion of a package structure, in accordance with some embodiments. In some embodiments, a package that is similar to the package structure shown in FIG. 1K is formed. In some embodiments, the conductive connectors bonded to the substrate 140 includes conductive pillars 302 and tin-containing solder bumps 304.

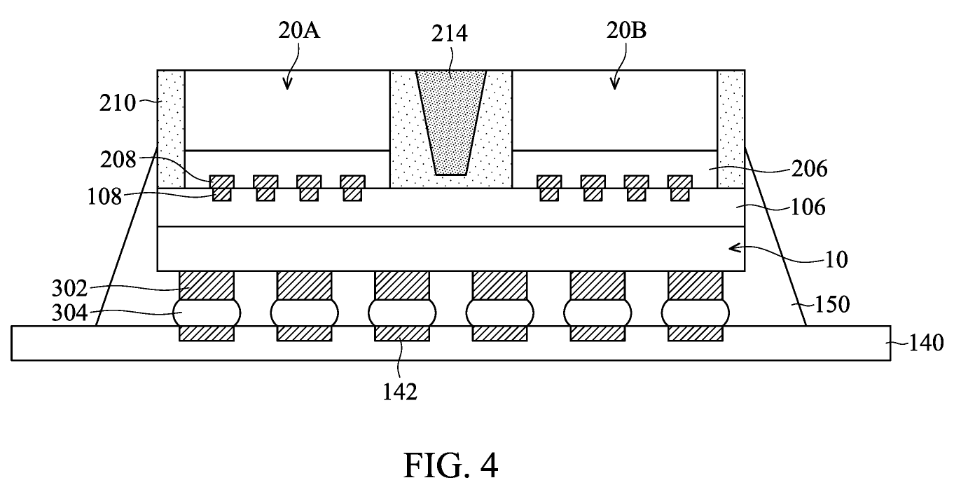

Many variations and/or modifications can be made to embodiments of the disclosure. FIG. 4 is a cross-sectional view of a portion of a package structure, in accordance with some embodiments. In some embodiments, a package that is similar to the package structure shown in FIG. 3 is formed. In some embodiments, the molding structure 214 has slanted sidewalls. In some embodiments, the molding structure 214 gradually shrinks along a direction towards the chip-containing structure 10. The profile of the molding structure 214 may be adjusted by fine-tuning the profile of the opening 212 that accommodates it.

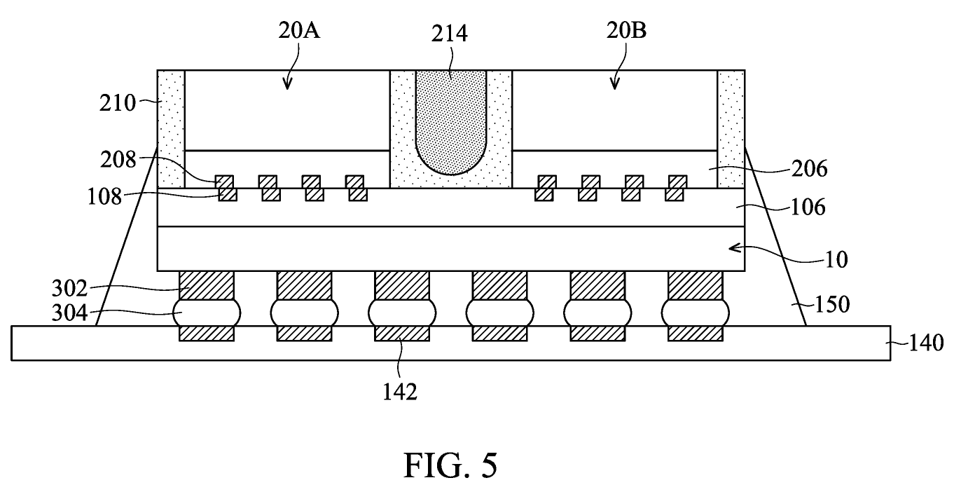

Many variations and/or modifications can be made to embodiments of the disclosure. FIG. 5 is a cross-sectional view of a portion of a package structure, in accordance with some embodiments. In some embodiments, a package that is similar to the package structure shown in FIG. 3 is formed. In some embodiments, the molding structure 214 has a rounded bottom surface. The profile of the molding structure 214 may be adjusted by fine-tuning the profile of the opening 212 that accommodates it.

Embodiments of the disclosure form a package structure with multiple bonded chip-containing structures. A first molding structure is formed to laterally surround nearby upper chip-containing structures. A second molding structure is formed between the nearby upper chip-containing structures. The second molding structure may help reinforce the critical chip-to-chip area, providing sufficient mechanical strength and stiffness. This significantly reduces deformations in the chip-to-chip gap area, preventing bonding layer cracking, delamination, and electrical failures. As a result, the performance and reliability of the package structure are greatly enhanced.

In accordance with some embodiments, a package structure is provided. The package structure includes a first upper chip-containing structure and a second upper-chip-containing structure over a lower chip-containing structure. The package structure also includes a first molding structure laterally surrounding the first upper chip-containing structure and the second upper chip-containing structure. The package structure further includes a second molding structure laterally surrounded by the first molding structure. Some or all of the second molding structure is between the first upper chip-containing structure and the second upper chip-containing structure.

In accordance with some embodiments, a package structure is provided. The package structure includes a lower chip-containing structure and an upper chip-containing structure bonded to the lower chip-containing structure through dielectric-to-dielectric bonding and metal-to-metal bonding. The package structure also includes a first molding structure laterally surrounding the upper chip-containing structure. The package structure further includes a second molding structure extending downwards from a top surface of the first molding structure towards the lower chip-containing structure. A portion of the first molding structure is between a bottom of the second molding structure and the lower chip-containing structure.

In accordance with some embodiments, a method for forming a package structure is provided. The method includes bonding a first chip-containing structure and a second chip-containing structure to a lower chip-containing structure. The method also includes forming a first protective layer laterally surrounding the first chip-containing structure and the second chip-containing structure. The method further includes partially removing the first protective layer to form an opening between the first chip-containing structure and the second chip-containing structure and forming a second protective layer in the opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first upper chip-containing structure and a second upper-chip-containing structure over a lower chip-containing structure;
a first molding structure laterally surrounding the first upper chip-containing structure and the second upper chip-containing structure; and
a second molding structure laterally surrounded by the first molding structure, wherein at least a portion of the second molding structure is between the first upper chip-containing structure and the second upper chip-containing structure.

2. The package structure as claimed in claim 1, wherein the second molding structure has a greater Young’s modulus than that of the first molding structure.

3. The package structure as claimed in claim 1, wherein the first upper chip-containing structure and the second upper chip-containing structure are separated from each other by a distance along a lateral direction, the second molding structure has a width measured along the lateral direction, and the distance is greater than the width.

4. The package structure as claimed in claim 3, wherein a ratio of the width to the distance is within a range from about 0.5 to about 0.9.

5. The package structure as claimed in claim 1, wherein the first upper chip-containing structure is bonded to the lower chip-containing structure through dielectric-to-dielectric bonding and metal-to-metal bonding.

6. The package structure as claimed in claim 5, wherein:
the first upper chip-containing structure has an upper metal bonding structure and an upper dielectric bonding structure laterally surrounding the upper metal bonding structure,
the lower chip-containing structure has a lower metal bonding structure and a lower dielectric bonding structure laterally surrounding the lower metal bonding structure,
the upper metal bonding structure is in contact with the lower metal bonding structure,
the upper dielectric bonding structure is in contact with the lower dielectric bonding structure, and
a first interface between the upper metal bonding structure and the lower metal bonding structure is aligned with a second interface between the upper dielectric bonding structure and the lower dielectric bonding structure.

7. The package structure as claimed in claim 6, wherein the upper metal bonding structure is in contact with the lower dielectric bonding structure, and the upper dielectric bonding structure is in contact with the lower metal bonding structure.

8. The package structure as claimed in claim 1, wherein the first molding structure has a first height, the second molding structure has a second height, and the first height is greater than the second height.

9. The package structure as claimed in claim 8, wherein a ratio of the second height to the first height is within a range from about 0.5 to about 0.9.

10. The package structure as claimed in claim 1, wherein in a top view, the second molding structure extends across opposite side edges of the first chip-containing structure.

11. A package structure, comprising:
a lower chip-containing structure;
an upper chip-containing structure bonded to the lower chip-containing structure through dielectric-to-dielectric bonding and metal-to-metal bonding;
a first molding structure laterally surrounding the upper chip-containing structure; and
a second molding structure extending downwards from a top surface of the first molding structure towards the lower chip-containing structure, wherein a portion of the first molding structure is between a bottom of the second molding structure and the lower chip-containing structure.

12. The package structure as claimed in claim 11, wherein:
the upper chip-containing structure has an upper metal bonding structure and an upper dielectric bonding structure laterally surrounding the upper metal bonding structure,
the lower chip-containing structure has a lower metal bonding structure and a lower dielectric bonding structure laterally surrounding the lower metal bonding structure,
the upper metal bonding structure is in contact with the lower metal bonding structure,
the upper dielectric bonding structure is in contact with the lower dielectric bonding structure, and
a first interface between the upper metal bonding structure and the lower metal bonding structure is aligned with a second interface between the upper dielectric bonding structure and the lower dielectric bonding structure.

13. The package structure as claimed in claim 12, wherein the upper metal bonding structure is in contact with the lower dielectric bonding structure, and the upper dielectric bonding structure is in contact with the lower metal bonding structure.

14. The package structure as claimed in claim 12, wherein the upper metal bonding structure partially overlaps the lower metal bonding structure and partially overlaps the lower dielectric bonding structure.

15. The package structure as claimed in claim 14, further comprising:
a second upper chip-containing structure over the lower chip-containing structure, wherein the first molding structure laterally surrounds the second molding structure, the first molding structure laterally surrounds the second upper chip-containing structure, and at least a portion of the second molding structure is between the upper chip-containing structure and the second upper chip-containing structure.

16. The package structure as claimed in claim 11, further comprising:
a third molding structure laterally surrounded by the first molding structure and located over the lower chip-containing structure.

17. A method for forming a package structure, comprising:
bonding a first chip-containing structure and a second chip-containing structure to a lower chip-containing structure;
forming a first protective layer laterally surrounding the first chip-containing structure and the second chip-containing structure;
partially removing the first protective layer to form an opening between the first chip-containing structure and the second chip-containing structure; and
forming a second protective layer in the opening.

18. The method for forming a package structure as claimed in claim 17, wherein a portion of the first protective layer is between the lower chip-containing structure and a bottom of the opening.

19. The method for forming a package structure as claimed in claim 17, wherein the second protective layer has a slanted sidewall.

20. The method for forming a package structure as claimed in claim 17, wherein the second protective layer has a rounded bottom surface.
